(19) United States
(12) Patent Application Publication
(10) Pub. No.: US 2025/0351360 A1
(43) Pub. Date: Nov. 13, 2025

(54) SEMICONDUCTOR DEVICE AND ELECTRONIC SYSTEM INCLUDING THE SAME

(71) Applicant: SAMSUNG ELECTRONICS CO., LTD., Suwon-si (KR)

(72) Inventors: Chulmin Choi, Suwon-si (KR); Geon Kook, Suwon-si (KR); Sanghoon Kim, Suwon-si (KR); Seungsob Kim, Suwon-si (KR); Tae Hun Kim, Suwon-si (KR); Seungjae Baik, Suwon-si (KR); Youngsoo Ahn, Suwon-si (KR); Nayeong Yun, Suwon-si (KR); Jaeduk Lee, Suwon-si (KR); Hyeongwon Choi, Suwon-si (KR)

(21) Appl. No.: 19/010,785

(22) Filed: Jan. 6, 2025

(30) Foreign Application Priority Data
May 13, 2024 (KR) 10-2024-0062506

(51) Int. Cl. H10B 43/35; H01L 23/00; H01L 25/065; H01L 25/18; H10B 43/27; H10B 80/00

(52) U.S. Cl. CPC H10B 43/35; H01L 24/08; H01L 25/0657; H01L 25/18; H10B 43/27; H10B 80/00; H01L 2224/08145; H01L 2924/1431; H01L 2924/14511

(57) ABSTRACT

A semiconductor device includes a stacked structure including a plurality of gate electrodes and a plurality of interlayer insulating layers that are alternately stacked, and a channel structure penetrating the stacked structure. The plurality of gate electrodes includes a first erase control gate electrode, and a plurality of word lines. The channel structure includes a first pad portion, as an upper end area of the channel structure, in which a first pad protruding downward from a source structure to a position overlapping the first erase control gate electrode in a horizontal direction is positioned, and a channel portion which is positioned on a lower side of the first pad portion and in which at least a portion of a core insulator penetrating the plurality of word lines is positioned. A largest width of the first pad portion is larger than a smallest width of the channel portion.

### CROSS-REFERENCE TO RELATED APPLICATION

This application claims the benefit of Korean Patent Application No. 10-2024-0062506 filed on May 13, 2024, in the Korean Intellectual Property Office, the entire disclosure of which is incorporated herein by reference for all purposes.

### BACKGROUND

Semiconductor device capable of storing a large amount of data in an electronic system that requires data storage are in demand. One way to increase the data storage capacity of a semiconductor device is to include three-dimensionally arranged memory cells instead of two-dimensionally arranged memory cells.

### SUMMARY

As the number of stacked structures included in a semiconductor device increases, a magnitude of a gate induced drain leakage (GIDL) current used in an erase operation of deleting data tends to decrease. Larger GIDL current generation areas can result in greater GIDL currents. The present disclosure includes a semiconductor device with increased GIDL current generation area, by forming a pad at an end portion of a channel structure so as to overlap an erase control gate electrode in a horizontal direction. Further, the characteristics of the pad are compatible with a narrow width of a channel structure.

In some implementations, a semiconductor device includes a structure capable of generating a GIDL current with a sufficiently high magnitude to be used in an erase operation.

In some implementations, a semiconductor device includes a pad formed at a position that overlaps an erase control gate electrode in a horizontal direction.

In some implementations, a space where an etching stopper previously existed is used as a space to form a pad.

In a first general aspect, a semiconductor device includes a stacked structure including a plurality of gate electrodes and a plurality of interlayer insulating layers that are alternately stacked, a source structure positioned on an upper portion of the stacked structure, a bit line positioned on a lower portion of the stacked structure, and a channel structure penetrating the stacked structure to connect the source structure and the bit line. The plurality of gate electrodes may include a first erase control gate electrode positioned on an upper end portion of the stacked structure, and a plurality of word lines on a lower side of the first erase control gate electrode. The channel structure may include a first pad portion, as an upper end area of the channel structure, in which a first pad protruding downward from the source structure to a position overlapping the first erase control gate electrode in a horizontal direction is positioned, and a channel portion which is positioned on a lower side of the first pad portion and in which at least a portion of a core insulator penetrating the plurality of word lines is positioned. A largest width of the first pad portion may be larger than a smallest width of the channel portion.

The first pad portion may have a largest width at a position where the first pad portion is connected to the channel portion. The channel portion may have a smallest width at a position where the channel portion is connected to the first pad portion.

The channel structure may have a width that is discontinuously narrowed at a position where the first pad portion and the channel portion are connected.

The channel structure may further include a gate dielectric layer and a channel poly layer stacked sequentially from outside to inside along a horizontal direction.

At least a portion of the gate dielectric layer or the channel poly layer may be bent inward to have a narrow width at a position where the first pad portion and the channel portion are connected.

The first pad may include a first layer positioned inside the channel poly layer and including undoped polysilicon, and a first pad core positioned inside the first layer and including doped polysilicon.

The first layer may include a first side wall layer surrounding an outer peripheral surface of the first pad core, and a first lower layer covering a lower surface of the first pad core.

The number of first erase control gate electrodes may be more than one, and the first pad may overlap at least a portion of the plurality of first erase control gate electrodes in a horizontal direction.

A lower end portion of the first pad may overlap a lowermost first erase control gate electrode positioned on a lowermost side of the plurality of first erase control gate electrodes in a horizontal direction, or may be positioned above the lowermost first erase control gate electrode.

The first pad portion may be an area filled with a metal material to limit an etching depth during a process of forming the channel structure in the stacked structure.

The plurality of gate electrodes may further include a second erase control gate electrode positioned on a lower end portion of the stacked structure. The channel structure may further include a second pad portion, as a lower end area of the channel structure, which is positioned on a lower side of the channel portion and in which a second pad overlapping the second erase control gate electrode in a horizontal direction is positioned.

The second pad may include a second layer positioned inside the channel poly layer, and including undoped polysilicon, and a second pad core positioned inside the second layer and including doped polysilicon.

An upper end portion of the core insulator may be positioned on the first pad portion.

The core insulator may include a main portion and an extended portion having a wider width than the main portion on an upper end of the main portion.

The source structure may include a recess into which the upper end of the channel structure is inserted and positioned.

In a second general aspect, an electronic system includes a main substrate, a semiconductor device disposed on the main substrate, and a controller disposed on the main substrate and electrically connected to the semiconductor device. The semiconductor device may include a stacked structure including a plurality of gate electrodes and a plurality of interlayer insulating layers that are alternately stacked, a source structure positioned on an upper portion of the stacked structure, a bit line positioned on a lower portion of the stacked structure, and a channel structure penetrating the stacked structure to connect the source structure and the bit line. The plurality of gate electrodes may include a first erase control gate electrode positioned on an upper end portion of the stacked structure, and a plurality of word lines on a lower side of the first erase control gate electrode. The channel structure may include a first pad portion, as an upper end area of the channel structure, in which a first pad protruding downward from the source structure to a position overlapping the first erase control gate electrode in a horizontal direction is positioned, and a channel portion which is positioned on a lower side of the first pad portion and in which at least a portion of a core insulator penetrating the plurality of word lines is positioned. A largest width of the first pad portion may be larger than a smallest width of the channel portion.

The first pad portion may have a largest width at a position where the first pad portion is connected to the channel portion. The channel portion may have a smallest width at a position where the channel portion is connected to the first pad portion.

The channel structure may further include a gate dielectric layer and a channel poly layer stacked sequentially from outside to inside along a horizontal direction.

At least a portion of the gate dielectric layer or the channel poly layer may be bent inward to have a narrow width at a position where the first pad portion and the channel portion are connected.

The first pad may include a first layer positioned inside the channel poly layer and including undoped polysilicon, and a first pad core positioned inside the first layer and including doped polysilicon.

Additional examples will be set forth in part in the description which follows and, in part, will be apparent from the description, or may be learned by practice of the disclosure.

A semiconductor device and an electronic system including the described semiconductor device may generate a Gate Induce Drain Leakage (GIDL) current having a size sufficient to be used in an erase operation by using a pad formed at a position that overlaps an erase control gate electrode in a horizontal direction.

In the semiconductor device and the electronic system including the semiconductor device, a space where the etching stopper has been existed may be utilized such that a pad may be formed in the space.

The effects of a semiconductor device and an electronic system including the semiconductor device are not limited to the above-mentioned effects, and other unmentioned effects may be clearly understood from the following description by one of ordinary skill in the art.

### BRIEF DESCRIPTION OF THE DRAWINGS

FIG. 1 is a diagram schematically illustrating an example of an electronic system including a semiconductor memory device.

FIG. 2 is a perspective view schematically illustrating an example of an electronic system including a semiconductor memory device.

FIG. 3 is a cross-sectional view schematically illustrating examples of semiconductor packages.

FIG. 4 is a cross-sectional view schematically illustrating a portion of an example of a semiconductor device.

FIG. 5A is a schematic cross-sectional view illustrating an example of an upper end portion of a channel structure, which is an enlarged view of a section C of FIG. 4.

FIG. 5B is a schematic cross-sectional view illustrating an example of a lower end portion of a channel structure, which is an enlarged view of a section D of FIG. 4.

FIGS. 6 to 12 are schematic cross-sectional views illustrating an example of a process of forming a channel structure and a first pad.

FIGS. 13 to 16 are schematic cross-sectional views illustrating an example of a process of forming a first pad.

FIG. 17 is a schematic cross-sectional view illustrating an example of an upper end portion of a channel structure.

When describing the examples with reference to the accompanying drawings, like reference numerals refer to like elements and a repeated description related thereto will be omitted.

### DETAILED DESCRIPTION

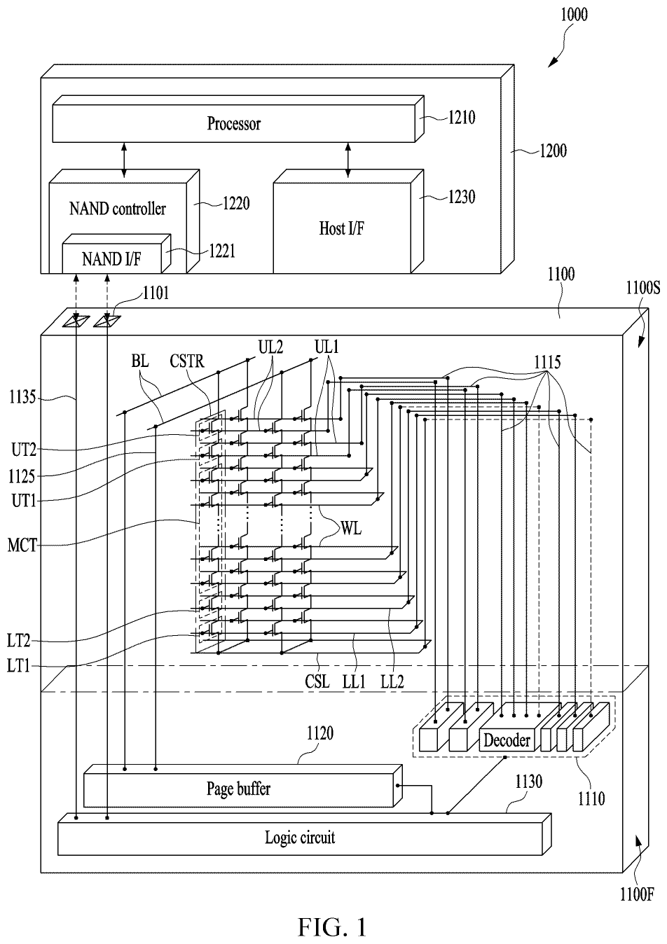

FIG. 1 is a diagram schematically illustrating an example of an electronic system including a semiconductor memory device.

Referring to FIG. 1, an electronic system 1000 includes a semiconductor memory device 1100 and a controller 1200 electrically connected to the semiconductor memory device 1100. The electronic system 1000 may be a storage device that includes a single or a plurality of semiconductor memory devices 1100 or may be an electronic device that includes the storage device. For example, the electronic system 1000 may be a solid-state drive (SSD) device, a Universal Serial Bus (USB), a computing system, a medical device, or a communication device, each of which includes a single or a plurality of semiconductor memory devices 1100.

In some implementations, the semiconductor memory device 1100 may be a nonvolatile memory device, such as a NAND flash memory device. The semiconductor memory device 1100 may include a first structure 1100F and a second structure 1100S on the first structure 1100F. In some implementations, the first structure 1100F may be arranged next to the second structure 1100S.

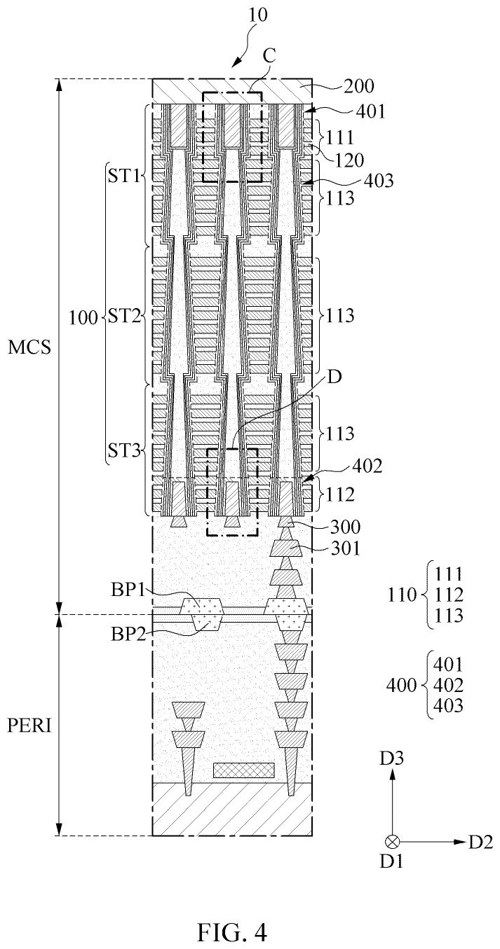

In some implementations, the first structure 1100F may be a peripheral circuit structure (e.g., a peripheral circuit structure PERI of FIG. 4) that includes a decoder circuit 1110, a page buffer 1120, and a logic circuit 1130. The second structure 1100S may be a memory cell structure (e.g., a memory cell structure MCS of FIG. 4) that includes bit lines BL, a common source line CSL, word lines WL, first and second gate upper lines UL1 and UL2, first and second gate lower lines LL1 and LL2, and memory cell strings CSTR between the bit line BL and the common source line CSL.

In some implementations, in the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may vary depending on the implementation.

In some implementations, the upper transistors UT1 and UT2 may include a string selection transistor, and the lower transistors LT1 and LT2 may include a ground selection transistor. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

In some implementations, the lower transistors LT1 and LT2 may include a lower erase control transistor LT1 and a ground selection transistor LT2 that are connected in series. The upper transistors UT1 and UT2 may include a string selection transistor UT1 and an upper erase control transistor UT2 that are connected in series. At least one of the lower erase control transistor LT1 and the upper erase control transistor UT2 may be used for an erasure operation of deleting data stored in the memory cell transistors MCT using a gate induced drain leakage (GIDL) current phenomenon.

In some implementations, the common source line CSL, the first and second gate lower lines LL1 and LL2, the word lines WL, and the first and second gate upper lines UL1 and UL2 may be electrically connected to the decoder circuit 1110 through first connection wires 1115 that extend from the first structure 1100F to the second structure 1100S. The bit lines BL may be electrically connected to the page buffer 1120 through second connection wires 1125 that extend from the first structure 1100F to the second structure 1100S.

In some implementations, in the first structure 1100F, the decoder circuit 1110 and the page buffer 1120 may perform a control operation on at least one selection memory cell transistor among the plurality of memory cell transistors MCT. The decoder circuit 1110 and the page buffer 1120 may be controlled by the logic circuit 1130. The semiconductor memory device 1100 may communicate with the controller 1200 through an input/output pad 1101 electrically connected to the logic circuit 1130. The input/output pad 1101 may be electrically connected to the logic circuit 1130 through an input/output connection wire 1135 that extends from the first structure 1100F to the second structure 1100S.

In some implementations, the first structure 1100F may include a voltage generator. The voltage generator may generate a program voltage, a read voltage, a pass voltage, and a verification voltage required for the operation of the memory cell strings CSTR. Here, the program voltage may be a relatively high voltage (e.g., 20 volts (V) to 40 V) compared to the read voltage, the pass voltage, and the verification voltage.

In some implementations, the first structure 1100F may include high-voltage transistors and low-voltage transistors. The decoder circuit 1110 may include pass transistors connected to the word lines WL of the memory cell strings CSTR. The pass transistors may include high-voltage transistors capable of withstanding high voltages such as the program voltage applied to the word lines WL in a program operation. The page buffer 1120 may also include high-voltage transistors capable of withstanding high voltages.

In some implementations, the controller 1200 may include a processor 1210, a NAND controller 1220, and a host interface 1230. In some implementations, the electronic system 1000 may include a plurality of semiconductor memory devices 1100, and in this case, the controller 1200 may control the plurality of semiconductor memory devices 1100.

In some implementations, the processor 1210 may control the overall operation of the electronic system 1000 including the controller 1200. The processor 1210 may operate based on predetermined firmware and may control the NAND controller 1220 to access the semiconductor memory device 1100. The NAND controller 1220 may include a NAND interface 1221 that processes communications with the semiconductor memory device 1100. Through the NAND interface 1221, a control command to control the semiconductor memory device 1100, data to be written to the memory cell transistors MCT of the semiconductor memory device 1100, and/or data to be read from the memory cell transistors MCT of the semiconductor memory device 1100 may be transmitted. The host interface 1230 may provide a communication function between the electronic system 1000 and an external host. When a control command is received through the host interface 1230 from an external host, the processor 1210 may control the semiconductor memory device 1100 in response to the control command.

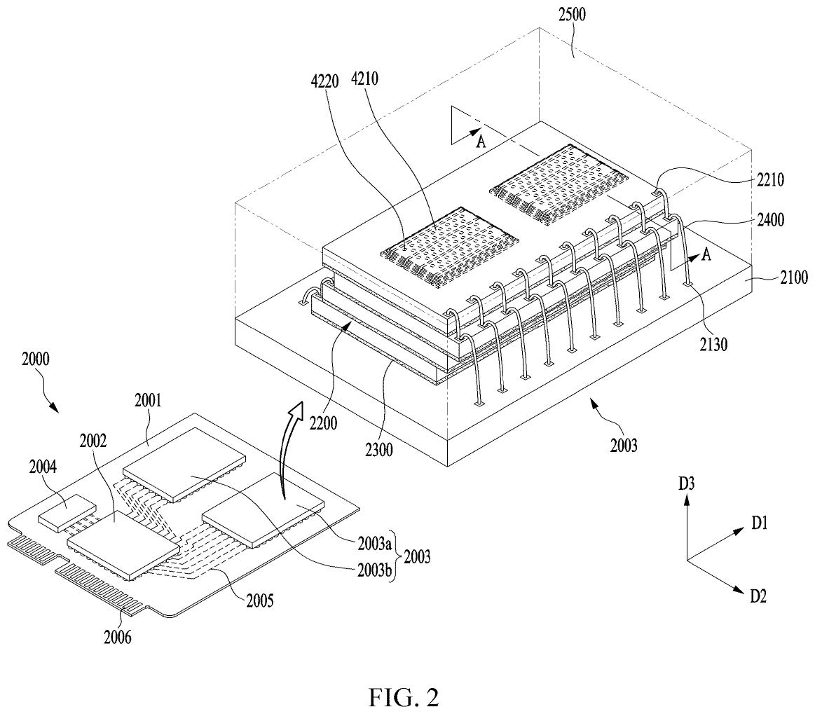

FIG. 2 is a perspective view schematically illustrating an example of an electronic system including a semiconductor memory device.

Referring to FIG. 2, an electronic system 2000 includes a main substrate 2001, a controller 2002 disposed on the main substrate 2001, one or more semiconductor packages 2003, and a dynamic random-access memory (DRAM) 2004. The semiconductor packages 2003 and the DRAM 2004 may be connected to the controller 2002 through wiring patterns 2005 formed on the main substrate 2001.

In some implementations, the main substrate 2001 may include a connector 2006 including a plurality of pins that are coupled to an external host. The number and arrangement of the plurality of pins on the connector 2006 may vary based on a communication interface between the electronic system 2000 and the external host. In some implementations, the electronic system 2000 may communicate with the external host according to one or more types of interfaces, for example, Universal Serial Bus (USB), Peripheral Component Interconnect Express (PCI-Express), Serial Advanced Technology Attachment (SATA), and M-PHY for Universal Flash Storage (UFS). In some implementations, the electronic system 2000 may operate with the power supplied through the connector 2006 from the external host. The electronic system 2000 may further include a power management integrated circuit (PMIC) to distribute the power supplied from the external host to the controller 2002 and the semiconductor packages 2003.

In some implementations, the controller 2002 may be electrically connected to the semiconductor package 2003. The controller 2002 may write data to the semiconductor packages 2003 or read data from the semiconductor packages 2003, thereby increasing an operating speed of the electronic system 2000.

In some implementations, the DRAM 2004 may be a buffer memory to reduce the speed difference between the external host and the semiconductor packages 2003 that serve as data storage spaces. The DRAM 2004 included in the electronic system 2000 may operate as a kind of cache memory and may provide a space for temporary data storage in a control operation on the semiconductor packages 2003. When the DRAM 2004 is included in the electronic system 2000, the controller 2002 may include not only a NAND controller for controlling the semiconductor packages 2003, but a DRAM controller for controlling the DRAM 2004.

In some implementations, the semiconductor packages 2003 may include first and second semiconductor packages 2003a and 2003b that are spaced apart from each other. The first and second semiconductor packages 2003a and 2003b may each be a semiconductor package including a plurality of semiconductor chips 2200 (e.g., a semiconductor device 10 of FIG. 4). Each of the first and second semiconductor packages 2003a and 2003b may include a package substrate 2100, semiconductor chips 2200 on the package substrate 2100, adhesion layers 2300 disposed on bottom surfaces of the semiconductor chips 2200, a connection structure 2400 that electrically connects the semiconductor chips 2200 to the package substrate 2100, and a molding layer 2500 that lies on the package substrate 2100 and covers the semiconductor chips 2200 and the connection structure 2400.

In some implementations, the package substrate 2100 may be a printed circuit board including upper pads 2130. Each of the semiconductor chips 2200 may include an input/output pad 2210. The input/output pad 2210 may correspond to the input/output pad 1101 of FIG. 1. Each of the semiconductor chips 2200 may include stacked structures 4210 and channel structures 4220. Each of the semiconductor chips 2200 may include a semiconductor device (e.g., the semiconductor device 10 of FIG. 4).

In some implementations, the connection structure 2400 may be a bonding wire that electrically connects the input/output pad 2210 and the upper pads 2130. Therefore, in each of the first and second semiconductor packages 2003a and 2003b, the semiconductor chips 2200 may be electrically connected to each other in a bonding wire manner and may be electrically connected to the upper pads 2130 of the package substrate 2100. In some implementations, in each of the first and second semiconductor packages 2003a and 2003b, the semiconductor chips 2200 may be electrically connected to each other through connection structures including through-silicon vias (TSVs) instead of the connection structures 2400 based on the bonding wire manner.

In some implementations, the controller 2002 and the semiconductor chips 2200 may be included in a single package. In some implementations, the controller 2002 and the semiconductor chips 2200 may be disposed on a separate interposer substrate other than the main substrate 2001, and the controller 2002 and the semiconductor chips 2200 may be connected to each other through wires formed on the interposer substrate.

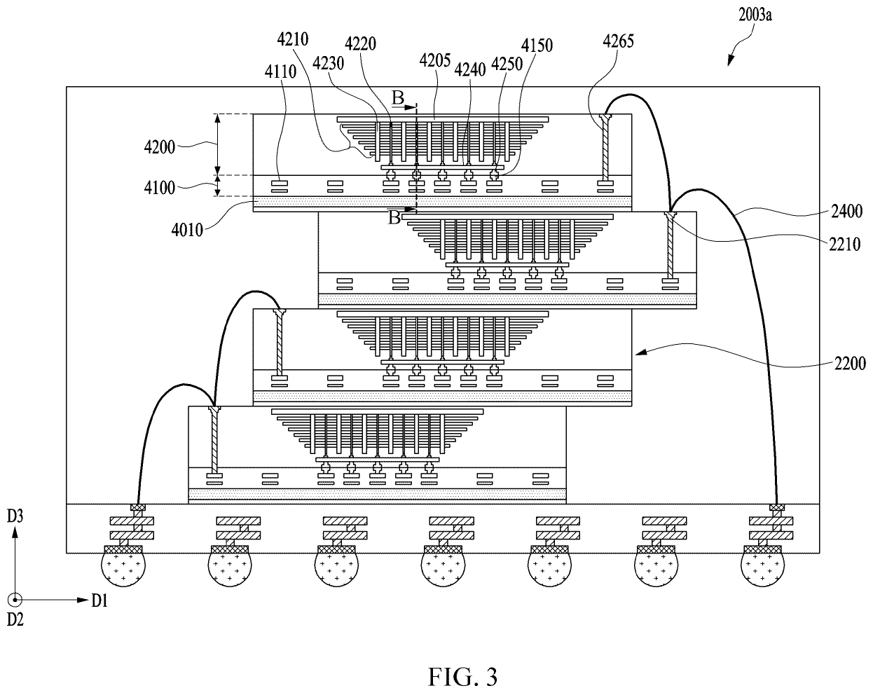

FIG. 3 is a cross-sectional view schematically illustrating examples of semiconductor packages. FIG. 3 depicts an example of a cross-section of the semiconductor package of FIG. 2 taken along line A-A.

Referring to FIG. 3, in the second semiconductor package 2003a, each of the semiconductor chips 2200 includes a semiconductor substrate 4010, a first structure 4100 on the semiconductor substrate 4010, and a second structure 4200 bonded to the first structure 4100 in a wafer bonding manner on the first structure 4100.

In some implementations, the first structure 4100 may include a peripheral circuit area including peripheral wires 4110 and first bonding structures 4150. The second structure 4200 may include a source structure 4205, a stacked structure 4210 between the source structure 4205 and the first structure 4100, channel structures 4220 and separation structures 4230 that penetrate the stacked structure 4210, and second bonding structures 4250 that are respectively electrically connected to the channel structures 4220 and word lines (e.g., the word lines WL of FIG. 1) of the stacked structure 4210. For example, the second bonding structures 4250 may be electrically connected to the channel structures 4220 and the word lines (e.g., the word lines WL of FIG. 1) respectively, through bit lines 4240 electrically connected to the channel structures 4220 and through cell contact plugs electrically connected to the word lines (e.g., the word lines WL of FIG. 1). The first bonding structures 4150 of the first structure 4100 and the second bonding structures 4250 of the second structure 4200 may be bonded to each other while being in contact with each other. Bonding portions of the first bonding structures 4150 and the second bonding structures 4250 may be formed of, for example, copper (Cu). Each of the semiconductor chips 2200 may further include an input/output connection wire 4265 that is electrically connected to the peripheral wires 4110 of the first structure 4100 and extends into the second structure 4200 and an input/output pad 2210 (e.g., the input/output pad 2210 of FIG. 2) that is electrically connected to the input/output connection wire 4265.

In some implementations, the semiconductor chips 2200 of FIG. 3 may be electrically connected to each other by connection structures 2400 in the form of bonding wires. In some implementations, the semiconductor chips 2200 in one semiconductor package including the semiconductor chips 2200 of FIG. 3 may be electrically connected to each other through connection structures including TSVs.

FIG. 4 is a cross-sectional view schematically illustrating an example of a portion of a semiconductor device. FIG. 4 is a cross-sectional view taken along line B-B of FIG. 3.

Referring to FIG. 4, a semiconductor device 10 includes a memory cell structure MCS and a peripheral circuit structure PERI. For example, the semiconductor device 10 may be understood as the semiconductor memory device 1100 of FIG. 1 and/or the semiconductor chip 2200 of FIG. 3. Hereinafter, an upper direction and a lower direction to be mentioned hereinafter may be understood as being based on an orientation state in each drawing. For example, in a case of FIG. 4, it may be understood that the upper direction refers to a +D3 direction, and the lower direction refers to a −D3 direction.

In some implementations, the memory cell structure MCS (e.g., the second structure 1100S of FIG. 1 and/or the second structure 4200 of FIG. 3) may be a structure including a plurality of memory cells. The memory cell structure MCS may include, for example, a stacked structure 100, a source structure 200, a bit line 300, and a channel structure 400. However, these are merely examples, and the configuration of the memory cell structure MCS is not limited thereto. The memory cell structure MCS may further include, for example, a separation structure (e.g., separation structure 4230 of FIG. 3) that separates each memory cell, a cell contact plug connected to each gate electrode, and a support structure that supports the stacked structure 100.

In some implementations, the peripheral circuit structure PERI (e.g., the first structure 1100F of FIG. 1 and/or the first structure 4100 of FIG. 3) may include a decoder circuit (e.g., decoder circuit 1110 of FIG. 1), a page buffer (e.g., page buffer 1120 of FIG. 1), and a logic circuit (e.g., logic circuit 1130 of FIG. 1). For example, the peripheral circuit structure PERI may be bonded to a lower portion of the memory cell structure MCS. For example, a first bonding pad BP1 may be positioned on the lower portion of the memory cell structure MCS, and a second bonding pad BP2 may be positioned on an upper portion of the peripheral circuit structure PERI. The memory cell structure MCS and the peripheral circuit structure PERI may be bonded to each other by the first bonding pad BP1 and the second bonding pad BP2. However, this is merely an example, and the peripheral circuit structure PERI may be positioned next to the memory cell structure MCS in a horizontal direction.

In some implementations, the stacked structure 100 (e.g., the stacked structure 4210 of FIG. 3) may include a plurality of gate electrodes 110 and a plurality of interlayer insulating layers 120 that are alternately stacked along a vertical direction D3. The plurality of gate electrodes 110 and the plurality of interlayer insulating layers 120 may extend along a horizontal direction (e.g., horizontal direction D2). The gate electrode 110 may include a conductive material. For example, the gate electrode 110 may include at least one of a doped semiconductor (e.g., doped silicon), a conductive metal (e.g., tungsten, copper, molybdenum, and/or aluminum), a conductive metal nitride (e.g., titanium nitride and/or tantalum nitride), or a transition metal (e.g., titanium and/or tantalum). However, these are merely examples, and the material of the gate electrode 110 is not limited thereto.

In some implementations, the gate electrode 110 may be used as the word lines WL, the gate upper lines UL1 and UL2, and/or the gate lower lines LL1 and LL2 described above with reference to FIG. 1. For example, the plurality of gate electrodes 110 may include a first erase control gate electrode 111 (e.g., the gate upper line UL2 of FIG. 1), a second erase control gate electrode 112 (e.g., the gate lower line LL1 of FIG. 1), and a plurality of word lines 113 (e.g., the word lines WL of FIG. 1). For example, the first erase control gate electrode 111 may be positioned on an upper end portion of the plurality of gate electrodes 110. For example, the first erase control gate electrode 111 may be positioned on an upper end portion of the stacked structure 100. For example, the number of first erase control gate electrodes 111 may be more than one. For example, the number of first erase control gate electrodes 111 may be 1, 2, 3, or more. The second erase control gate electrode 112 may be positioned on a lower end portion of the plurality of gate electrodes 110. For example, the second erase control gate electrode 112 may be positioned on a lower end portion of the stacked structure 100. For example, the number of second erase control gate electrodes 112 may be more than one. For example, the number of second erase control gate electrodes 112 may be 1, 2, 3, or more. The first erase control gate electrodes 111 and the second erase control gate electrodes 112 may be used for an erase operation using the GIDL current phenomenon. The plurality of word lines 113 may be positioned on a lower portion of the first erase control gate electrodes 111. The plurality of word lines 113 may be positioned between the first erase control gate electrodes 111 and the second erase control gate electrodes 112.

In some implementations, each the plurality of interlayer insulating layers 120 may be positioned between adjacent two gate electrodes 110. The interlayer insulating layers 120 may include an insulating material. The interlayer insulating layers 120 may include, for example, at least one of silicon oxide, silicon nitride, or silicon oxynitride. However, this are merely examples, and the material of the interlayer insulating layer 120 is not limited thereto.

In some implementations, the stacked structure 100 may include a plurality of cell stacks ST1, ST2, and ST3 stacked in a vertical direction (e.g., vertical direction D3). Each of the cell stacks ST1, ST2, and ST3 may include the plurality of gate electrodes 110 and the plurality of interlayer insulating layers 120. Each of the cell stacks ST1, ST2, and ST3 may be understood as a portion manufactured by a set of processes. The drawing shows three cell stacks ST1, ST2, and ST3. This is, however, for convenience of description, and the number of cell stacks is not limited thereto.

In some implementations, the source structure 200 (e.g., the common source line CSL of FIG. 1 and/or the source structure 4205 of FIG. 3) may be positioned on an upper portion of the stacked structure 100. The source structure 200 may include polysilicon and/or a conductive material containing impurities. For example, the source structure 200 may include n-type conductive polysilicon and/or metal (e.g., tungsten). The source structure 200 may come into contact with the channel structure 400 to provide a common source area. A separate cover layer that protects the source structure 200 may be disposed on an upper portion of the source structure 200.

In some implementations, the bit line 300 (e.g., the bit line BL of FIG. 1 and/or the bit line 4240 of FIG. 3) may be positioned on a lower portion of the stacked structure 100. The bit line 300 may be electrically connected to the channel structure 400. The bit line 300 may be electrically connected to the peripheral circuit structure PERI through a wiring structure 301 formed on the lower portion of the memory cell structure MCS. However, the bit line 300 shown in the drawing is merely an example, and the number and/or position of the bit line 300 are not limited thereto. For example, the bit line 300 may be connected to the channel structure 400 through a separate contact metal.

In some implementations, the channel structure 400 (e.g., the channel structure 4220 of FIG. 3) may penetrate the stacked structure 100 in the vertical direction (e.g., vertical direction D3). The channel structure 400 may connect the source structure 200 and the bit line 300. For example, an upper end of the channel structure 400 may be connected to the source structure 200, and a lower end of the channel structure 400 may be connected to the bit line 300. The number of channel structures 400 may be more than one, and the plurality of channel structures 400 may be arranged in a designated pattern. For example, the plurality of channel structures 400 may be arranged in a grid pattern or arranged in a zigzag form.

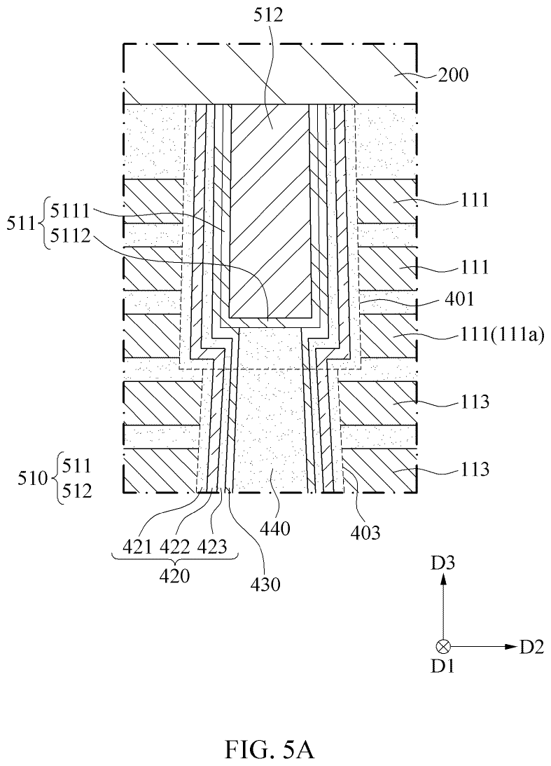

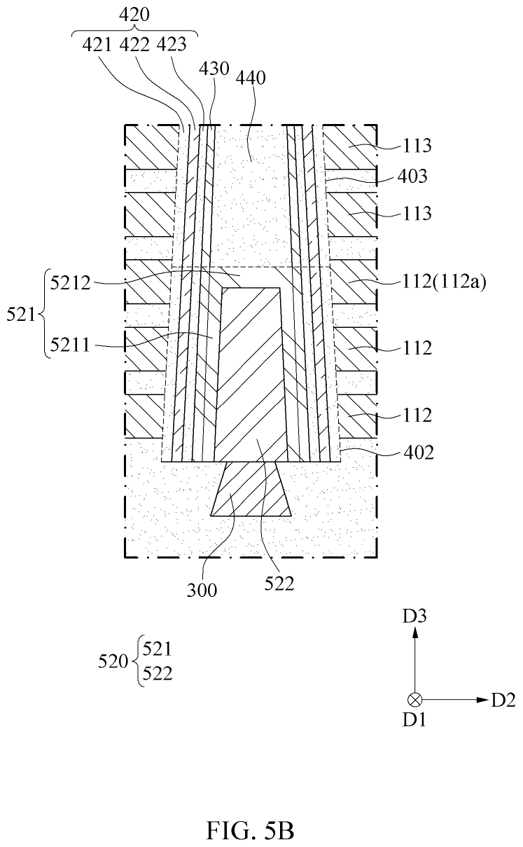

In some implementations, the channel structure 400 may include a first pad portion 401, a second pad portion 402, and a channel portion 403. The first pad portion 401 may refer to an upper end area of the channel structure 400. The first pad portion 401 may be an area where a first pad to be described below (e.g., 510 of FIG. 5A) is positioned. The first pad portion 401 may be an area that overlaps the first erase control gate electrode 111 in a horizontal direction. The second pad portion 402 may refer to a lower end area of the channel structure 400. The second pad portion 402 may be an area where a second pad (to be described below.

e.g., 520 of FIG. 5B) is positioned. The second pad portion 402 may be an area that overlaps the second erase control gate electrode 112 in the horizontal direction. The channel portion 403 may refer to an area between the first pad portion 401 and the second pad portion 402. The channel portion 403 may be an area where at least a portion of a core insulator to be described below (e.g., core insulator 440 of FIGS. 5A and 5B) is positioned. The channel portion 403 may be an area that overlaps the word line 113 in the horizontal direction. The channel portion 403 may be positioned on a lower side of the first pad portion 401. The second pad portion 402 may be positioned on a lower side of the channel portion 403.

FIG. 5A is a schematic cross-sectional view illustrating an example of an upper end portion of a channel structure, which is an enlarged view of a section C of FIG. 4. FIG. 5B is a schematic cross-sectional view illustrating a lower end portion of a channel structure, which is an enlarged view of a section D of FIG. 4.

Referring to FIGS. 4, 5A, and 5B, the channel structure 400 includes a first pad 510, a second pad 520, a gate dielectric layer 420, a channel poly layer 430, and a core insulator 440.

In some implementations, the gate dielectric layer 420 and the channel poly layer 430 may be stacked sequentially from outside to inside along a horizontal direction (e.g., the horizontal direction D2) in the channel structure 400. The gate dielectric layer 420 and the channel poly layer 430 may be positioned across the first pad portion 401, the channel portion 403, and the second pad portion 402. For example, the gate dielectric layer 420 and the channel poly layer 430 may be formed in an annular shape to surround the first pad 510, the core insulator 440, and the second pad 520 from the outside. The gate dielectric layer 420 may include a blocking layer 421, an information storage layer 422, and a tunneling layer 423. The blocking layer 421, the information storage layer 422, and the tunneling layer 423 may be stacked sequentially from the outside to the inside along the horizontal direction (e.g., the horizontal direction D2) in the channel structure 400. The blocking layer 421 may be a layer to insulate between the gate electrode 110 and the information storage layer 422. For example, the blocking layer 421 may include silicon oxide (SiO), silicon oxynitride (SiON), a high-k dielectric material, or a combination thereof. The information storage layer 422 may be an electron trap layer. The information storage layer 422 may include, for example, silicon nitride (SiN). The tunneling layer 423 may cause electrons to tunnel to the information storage layer 422. The tunneling layer 423 may include, for example, silicon oxide (SiO), silicon oxynitride (SiON), or a combination thereof. The channel poly layer 430 may serve as a passage for a carrier to move between a source and a drain. For example, the channel poly layer 430 may include a semiconductor material such as polysilicon. For example, the channel poly layer 430 may include undoped polysilicon. However, these are merely examples, and the materials of the blocking layer 421, the information storage layer 422, the tunneling layer 423, and the channel poly layer 430 are not limited thereto.

In some implementations, the first pad 510 may be positioned in first pad portion 401. The first pad 510 may protrude downward from the source structure 200 to a position that overlaps the first erase control gate electrode 111 in the horizontal direction. There may be two or more first erase control gate electrodes 111, and the first pad 510 may overlap at least a portion of the plurality of first erase control gate electrodes 111 in the horizontal direction. For example, the first pad 510 may protrude from the source structure 200 to a position that is not lower than a lowermost first erase control gate electrode 111a positioned at a lowermost side among the plurality of first erase control gate electrode 111. For example, a lower end portion of the first pad 510 may horizontally overlap the lowermost first erase control gate electrode 111a positioned at the lowermost side among the plurality of first erase control gate electrodes 111 or may be positioned above the lowermost first erase control gate electrode 111a. When the lower end portion of the first pad 510 is positioned below the lowermost first erase control gate electrode 111a, a threshold voltage may be affected. The number of first erase control gate electrodes 111 shown in the drawing is merely an example, and the number of first erase control gate electrodes 111 is not limited thereto.

In some implementations, the first pad 510 may include a first layer 511 and a first pad core 512. The first layer 511 may be positioned inside the channel poly layer 430 in the first pad portion 401. The first layer 511 may include undoped polysilicon. The first pad core 512 may be positioned inside the first layer 511. The first pad core 512 may include polysilicon doped with impurities (e.g., n-type impurities). The first layer 511 may be formed to surround a side surface and a bottom surface of the first pad core 512. For example, the first layer 511 may include a first side wall layer 5111 and a first lower layer 5112. The first side wall layer 5111 may surround an outer peripheral surface of the first pad core 512. The first lower layer 5112 may cover a bottom surface of the first pad core 512. The first lower layer 5112 may be positioned between the bottom surface of the first pad core 512 and an upper surface of the core insulator 440. In FIG. 5A, the first layer 511 and the channel poly layer 430 are shown as distinct components. In some implementations, however, the first layer 511 and the channel poly layer 430 include substantially the same material, so an interface between the first layer 511 and the channel poly layer 430 may not be observed in those implementations.

In some implementations, the second pad 520 may be positioned in the second pad portion 402. The second pad 520 may be positioned to overlap the second erase control gate electrode 112 in the horizontal direction. For example, the second pad 520 may protrude upward from the bit line 300 (or a contact metal connected to the bit line 300) to a position that overlaps the second erase control gate electrode 112 in the horizontal direction. The number of second erase control gate electrodes 112 may be more than one, and the second pad 520 may overlap at least a portion of the plurality of second erase control gate electrodes 112 in the horizontal direction. For example, the second pad 520 may protrude from the bit line 300 to a position that is not above an uppermost second erase control gate electrode 112a positioned at an uppermost side among the plurality of second erase control gate electrode 112. For example, an upper end portion of the second pad 520 may horizontally overlap the uppermost second erase control gate electrode 112a positioned at the uppermost side among the plurality of second erase control gate electrodes 112. Alternatively, the upper end portion of the second pad 520 may be positioned on a lower side of the uppermost second erase control gate electrode 112a. When the upper end portion of the second pad 520 is positioned above the uppermost second erase control gate electrode 112a, a threshold voltage may be affected. The number of second erase control gate electrodes 112 shown in the drawing is merely an example, and the number of second erase control gate electrodes 112 is not limited thereto.

In some implementations, the second pad 520 may include a second layer 521 and a second pad core 522. The second layer 521 may be positioned inside the channel poly layer 430 in the second pad portion 402. The second layer 521 may include undoped polysilicon. The second pad core 522 may be positioned inside the second layer 521. The second pad core 522 may include polysilicon doped with impurities (e.g., n-type impurities). The second layer 521 may be formed to surround a side surface and an upper surface of the second pad core 522. For example, the second layer 521 may include a second side wall layer 5211 and a second upper layer 5212. The second side wall layer 5211 may surround an outer peripheral surface of the second pad core 522. The second upper layer 5212 may cover an upper surface of the second pad core 522. For example, the second upper layer 5212 may be positioned between the upper surface of the second pad core 522 and a lower surface of the core insulator 440. In FIG. 5A, the second layer 521 and the channel poly layer 430 are shown separately. In some implementations, however, since the second layer 521 and the channel poly layer 430 can include substantially the same material, an interface between the second layer 521 and the channel poly layer 430 may not be observed.

In some implementations, at least a portion of the core insulator 440 may be positioned inside the channel poly layer 430 in the channel portion 403. For example, the core insulator 440 may penetrate the plurality of word lines 113. For example, the core insulator 440 may be formed substantially in a pillar shape. For example, the core insulator 440 may be positioned across the first pad portion 401 and the channel portion 403. For example, an upper end portion of the core insulator 440 may be positioned at the first pad portion 401. For example, the upper end portion of the core insulator 440 may contact the first pad 510, and a lower end portion of the core insulator 440 may contact the second pad 520. For example, the core insulator 440 may include silicon oxide or a low-k dielectric material. However, these are merely examples, and the position, shape, and/or material of the core insulator 440 are not limited thereto.

In some implementations, a largest width along the horizontal direction D2 of the first pad portion 401 may be greater than a smallest width of the channel portion 403 along the horizontal direction D2. The first pad portion 401 may have a largest width at a position where the first pad portion 401 is connected to the channel portion 403. For example, the first pad portion 401 may be widest near a lower end portion (e.g., lower along the vertical D3 direction). The channel portion 403 may be narrowest, e.g., have a smallest width, at a position where the channel portion 403 is connected to the first pad portion 401. For example, the channel portion 403 may have a smallest width at the upper end portion (e.g., higher along the vertical +D3 direction). At the position where the first pad portion 401 and the channel portion 403 are connected, the width of the first pad portion 401 may be larger than the width of the channel portion 403. At the position where the first pad portion 401 and the channel portion 403 are connected, at least a portion of the gate dielectric layer 420 and/or the channel poly layer 430 may be bent inward to narrow the width. For example, the width of the channel structure 400 may be discontinuously narrowed at the position where the first pad portion 401 and the channel portion 403 are connected. For example, the position where the first pad portion 401 and the channel portion 403 are connected may be understood as a position where the width of the channel structure 400 is discontinuously narrowed. For example, an upper portion of the channel structure 400 may be understood as the first pad portion 401 and a lower portion thereof may be understood as the channel portion 403, bordering the position where the width of the channel structure 400 is discontinuously narrowed. In other words, the width measured along the horizontal direction D2 changes abruptly with a stepwise variation in width. The position where the second pad portion 402 and the channel portion 403 are connected, a width of the second pad portion 402 may be substantially the same as the width of the channel portion 403. For example, widths of the gate dielectric layer 420 and/or the channel poly layer 430 may be continuously widened in a section connecting the second pad portion 402 to the channel portion 403. For example, in the state of FIG. 5A, the width of the first pad portion 401 may increase as it goes downward. For example, in the state of FIG. 5B, the width of the second pad portion 402 may increase as it goes downward. For example, in the state of FIG. 4, the width of the channel portion 403 may increase as it goes downward for each of the cell stacks ST1, ST2, and ST3. The width of the channel structure 400 may refer to a diameter of an outermost layer (e.g., the blocking layer 421). The width of the first pad portion 401, the width of the second pad portion 402, and the width of the channel portion 403 may refer to a diameter of an outermost layer (e.g., the blocking layer 421) of the channel structure 400 in each area.

In some implementations, the first pad portion 401 may be an area filled with a metal material to limit an etching depth during the process of forming the channel structure 400 in the stacked structure 100. For example, the first pad portion 401 may be an area that functions as an etching stopper in the process of forming the channel structure 400 in the stacked structure 100. Since the etching stopper is formed to have a larger width than that of the channel structure 400, the first pad 510 may be easily formed in the place where the etching stopper is etched and removed. This will be described below in detail.

In some implementations, the first pad 510 and the second pad 520 may be used in the erase operation to delete data stored in the channel structure 400 using the GIDL current phenomenon. Hereinafter, the erase operation will be described based on the first pad 510. The first layer 511 of the first pad 510 may serve as a diffusion buffer layer between the channel poly layer 430 and the first pad core 512. For example, to form a depletion area, the first layer 511 may diffuse impurities from the first pad core 512 to form a concentration gradient of the impurities, thereby buffering the diffusion of the impurities. The depletion area may be formed in a portion of the first layer 511 that overlaps the first erase control gate electrode 111 in the horizontal direction. During the erase operation of the semiconductor device 10, electron-hole pairs are formed in the depletion area and a GIDL current may be induced.

Since the first pad 510 overlaps the first erase control gate electrode 111 in the horizontal direction, the area where the GIDL current is generated during the erase operation of the semiconductor device 10 may be increased. Since the first layer 511, which is the diffusion buffer layer, overlaps the first erase control gate electrode 111 in the horizontal direction, a GIDL current with excellent horizontal band-to-band tunneling (BTBT) may be generated between the channel poly layer 430 and the first layer 511, and a GIDL current generation area may be increased by the area overlapping. Therefore, as the GIDL current generation area increases, the GIDL current generation efficiency during the erase operation of the semiconductor device 10 may be improved. The above erase operation has been described based on the first pad 510, but substantially the same description may be applied to the second pad 520.

In some implementations, the GIDL current generation area may be increased by using the first pad 510 positioned on the upper end of the channel structure 400 and/or the second pad 520 positioned on the lower end of the channel structure 400, thereby improving the GIDL current generation efficiency during the erase operation of the semiconductor device 10. According to such a structure, even when a height of the stacked structure 100 increases, a GIDL current having a sufficient magnitude required for the erase operation of the semiconductor device 10 may be generated.

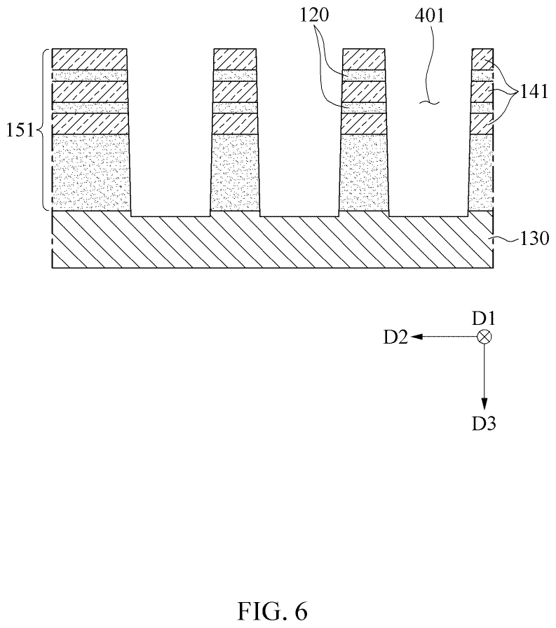

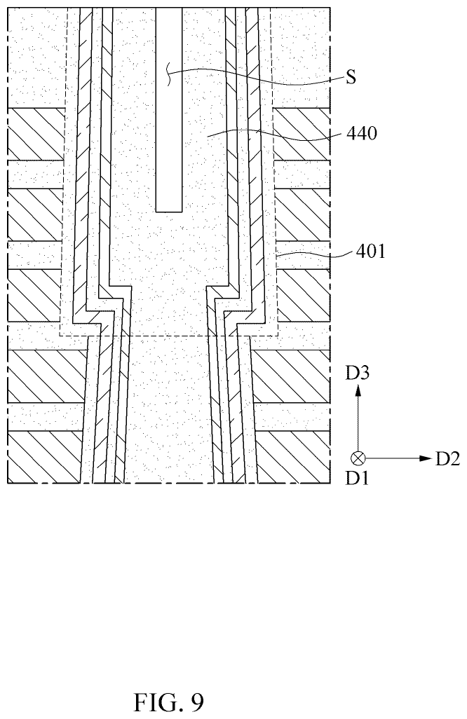

FIGS. 6 to 12 are schematic cross-sectional views illustrating an example of a process of forming a channel structure and a first pad. FIGS. 6 to 8 are cross-sectional views of a mold structure, and FIGS. 9 to 12 are enlarged cross-sectional views of an upper end portion of one channel structure.

Referring to FIG. 6, a first mold structure 151 is stacked on a sacrificial substrate 130. The first mold structure 151 may include interlayer insulating layers 120 and first sacrificial insulating layers 141 that are alternately stacked. The interlayer insulating layer 120 and the first sacrificial insulating layers 141 may each be stacked in multiple layers. The first mold structure 151 may be a portion of the cell stack ST1 of FIG. 4. The first sacrificial insulating layer 141 may be replaced with the first erase control gate electrode 111 of FIG. 5A through a later process. For example, the number of the first sacrificial insulating layers 141 may be the same as the number of the first erase control gate electrodes 111.

Through an etching process, a portion of the first mold structure 151 may be removed to form the first pad portion 401 in the first mold structure 151. In the state of FIG. 6, the first pad portion 401 may be an open space. For example, the first pad portion 401 may be formed to penetrate the first mold structure 151 downward from an upper end of the first mold structure 151. In the state of FIG. 6, the width of the first pad portion 401 may decrease as it goes downward.

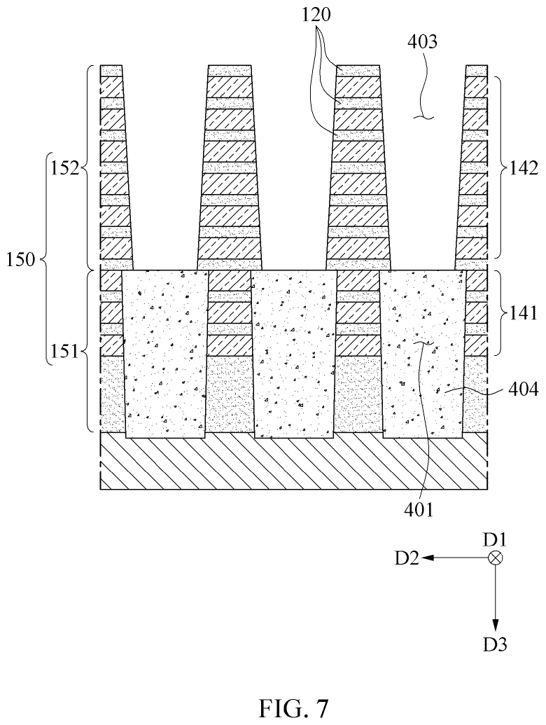

Referring to FIG. 7, the open first pad portion 401 may be filled with a metal material (e.g., tin nitride and/or tungsten). For example, the first pad portion 401 may be filled with a metal material, and the metal material remaining on the upper end may be removed through a chemical mechanical polishing (CMP) process. The metal material filled in the first pad portion 401 may function as an etching stopper 404. The etching stopper 404 may be a structure to limit the etching depth.

A second mold structure 152 may be further stacked on the first mold structure 151. The second mold structure 152 may include the interlayer insulating layers 120 and second sacrificial insulating layers 142 that are alternately stacked. The interlayer insulating layers 120 and the second sacrificial insulating layers 142 may each be stacked in multiple layers. The first mold structure 151 and the second mold structure 152 may substantially form one mold structure 150. The mold structure 150 may be a portion corresponding to the cell stack ST1 of FIG. 4. The second sacrificial insulating layers 142 may be replaced with the word lines 113 of FIG. 5A through a later process. After the second mold structure 152 is stacked, at least a portion of the channel portion 403 may be formed in the second mold structure 152 through an etching process. In the state of FIG. 7, the channel portion 403 may be an open space. For example, the channel portion 403 may be formed to penetrate the second mold structure 152 downward only from an upper end of the second mold structure 152 to an upper end of the etching stopper 404. For example, during the etching process (e.g., a dry etching process) to form the channel portion 403, the etching stopper 404 may not be etched due to selectivity. Accordingly, the etching stopper 404 may limit the etching depth, and the mold structure 150 may be etched and removed only up to the upper end of the etching stopper 404. In the state of FIG. 7, the width of the channel portion 403 may decrease as it goes downward. Referring to FIG. 7, at the position where the first pad portion 401 and the channel portion 403 are connected, the width of the first pad portion 401 may be larger than the width of the channel portion 403. For example, a largest width of the first pad portion 401 may be greater than a smallest width of the channel portion 403. The first pad portion 401 may have the largest width at a position where the first pad portion 401 is connected to the channel portion 403. The channel portion 403 may have a smallest width at a position where the channel portion 403 is connected to the first pad portion 401. For example, since the first pad portion 401 is an area filled with the etching stopper 404, the width thereof may be formed to be greater than the width of the channel portion 403. When the channel portion 403 is formed, the etching stopper 404 may be removed through an etching process (e.g., a wet etching process). Then, the open first pad portion 401 and channel portion 403 may be filled with a sacrificial material. Thereafter, an additional mold structure may be stacked on the top of the mold structure 150 to form an additional cell stack (e.g., cell stacks ST2 and ST3 of FIG. 4). The remaining portion of the channel portion 403 may be formed in the additional cell stack (e.g., cell stacks ST2 and ST3 of FIG. 4).

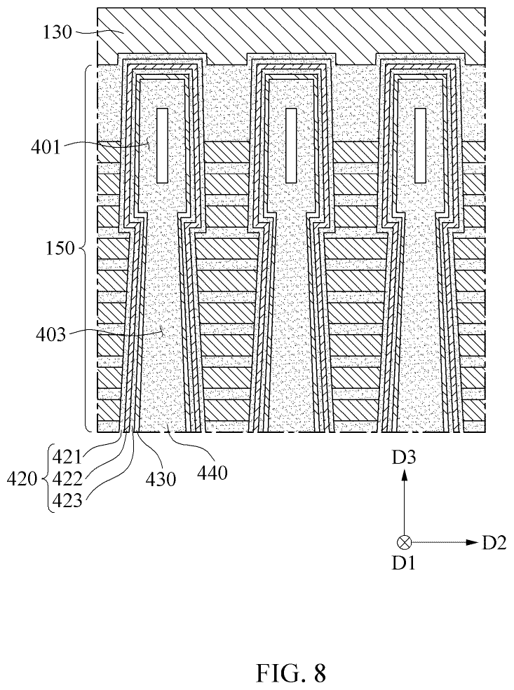

Referring to FIG. 8, the sacrificial material filled in the first pad portion 401 and the channel portion 403 may be removed, and the gate dielectric layer 420 (e.g., the blocking layer 421, the information storage layer 422, and the tunneling layer 423), the channel poly layer 430, and the core insulator 440 may be formed in the first pad portion 401 and the channel portion 403. The first sacrificial insulating layer 141 and the second sacrificial insulating layer 142 of FIG. 7 may be replaced with a conductive material. For example, the first sacrificial insulating layer 141 and the second sacrificial insulating layer 142 of FIG. 7 may be replaced with a first erase control gate electrode (e.g., erase control gate electrode 111 of FIG. 5A) and a word line (e.g., word line 113 of FIG. 5A), respectively.

A second pad (e.g., second pad 520 of FIG. 5B), a bit line (e.g., bit line 300 of FIG. 4), a wiring structure (e.g., wiring structure 301 of FIG. 4), and/or a first bonding pad (e.g., bonding pad BP1 of FIG. 4) may be formed on the upper end (e.g., a portion in the −D3 direction in FIG. 7) of the mold structure 150, and then, the mold structure 150 may be flipped in orientation shown in FIG. 8 and bonded to a peripheral circuit structure (e.g., peripheral circuit structure PERI of FIG. 4). Thereafter, the sacrificial substrate 130 of FIG. 8 may be removed through grinding, CMP, and/or etching processes.

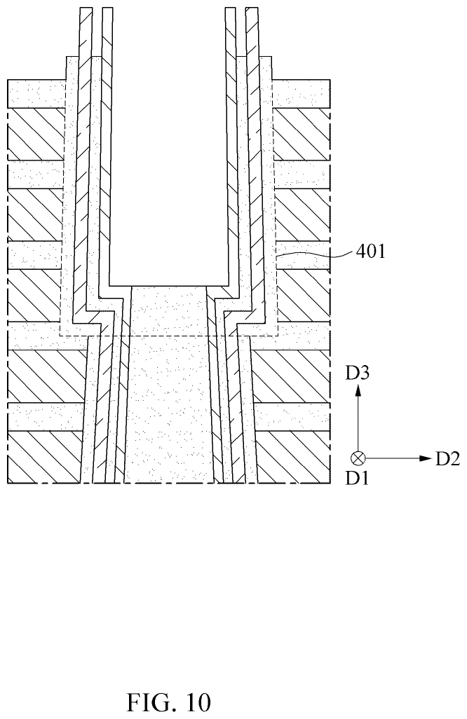

Referring to FIG. 9, the upper portion of the first pad portion 401 may be removed through the CMP process. For example, as shown in FIG. 9, a seam S inside the core insulator 440 may be opened by the CMP process. Thereafter, as shown in FIG. 10, the core insulator (e.g., core insulator 440 of FIG. 9) inside the first pad portion 401 may be removed through an etching process (e.g., a wet etching process and/or a dry etching process), and the first pad portion 401 may be open.

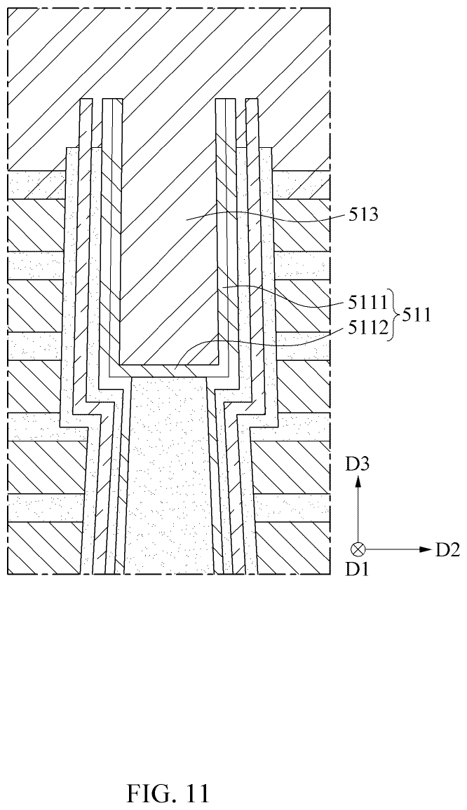

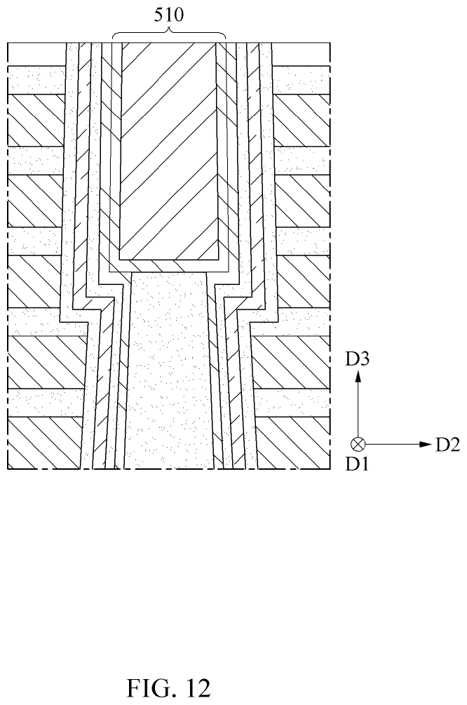

Referring to FIG. 11, undoped polysilicon may be applied to the open interior of the first pad portion (e.g., first pad portion 401 of FIG. 10) to form the first layer 511. For example, the first side wall layer 5111 and the first lower layer 5112 may be formed. In this process, since the width of the first pad portion 401 is sufficiently large, both first side wall layers 5111 may not contact each other and a space may be formed between them. Then, the inner space formed by the first layer 511 may be filled with polysilicon 513 doped with impurities (e.g., n-type impurities). Thereafter, as shown in FIG. 12, the upper portion of the doped polysilicon (e.g., polysilicon 513 of FIG. 11) may be removed through grinding, CMP, and/or etching processes to form the first pad 510. Thereafter, a source structure (e.g., the source structure 200 of FIG. 5A) may be formed on the upper portion of the first pad 510.

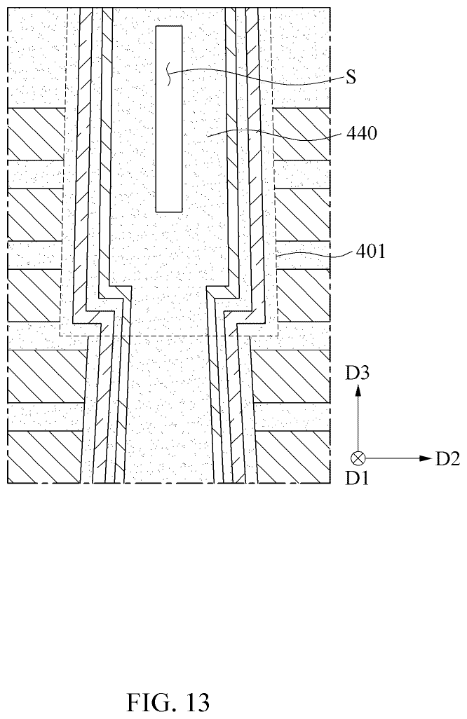

FIGS. 13 to 16 are schematic cross-sectional views illustrating an example of a process of forming a first pad. FIG. 13 is a diagram illustrating steps after the state of FIG. 8.

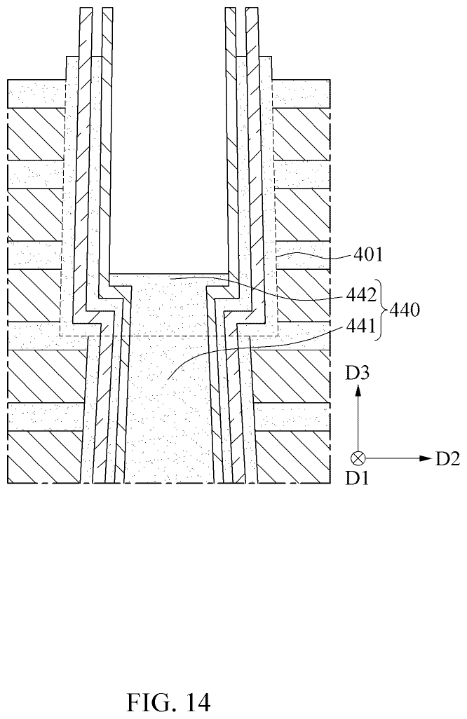

Referring to FIG. 13, the upper portion of the first pad portion 401 may be removed through the CMP process. For example, as shown in FIG. 13, the upper portion of the first pad portion 401 may be removed to a position where the seam S inside the core insulator 440 is not open. Then, as shown in FIG. 14, the core insulator 440 inside the first pad portion 401 may be removed through an etching process (e.g., a wet etching process and/or a dry etching process), and the first pad portion 401 may be opened. As shown in FIG. 14, an extended portion 442 having a larger width than a main portion 441 may remain at the top of the core insulator 440.

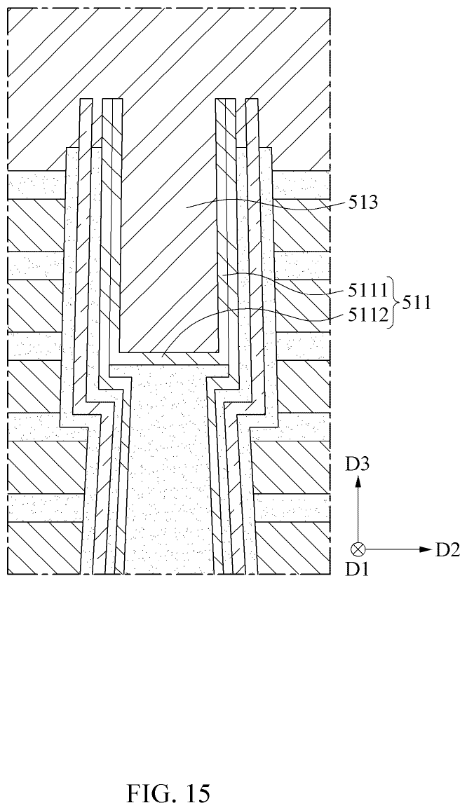

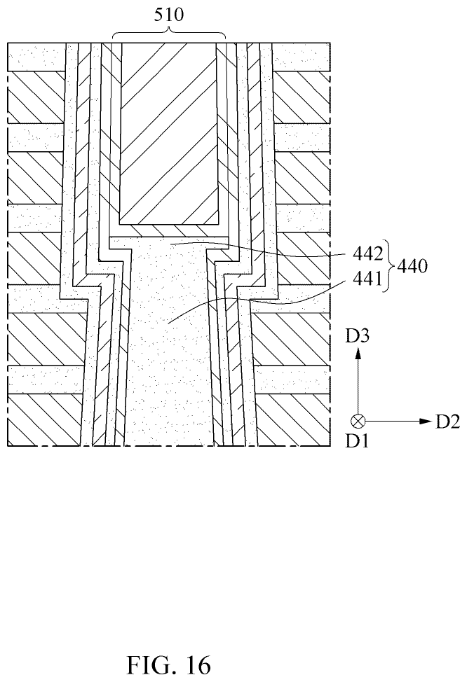

Referring to FIG. 15, undoped polysilicon may be applied to the open interior of the first pad portion (e.g., 401 of FIG. 14) to form the first layer 511. For example, the first side wall layer 5111 and the first lower layer 5112 may be formed. In this process, since the width of the first pad portion 401 is sufficiently large, both first side wall layers 5111 may not contact each other and a space may be formed between them. Then, the inner space formed by the first layer 511 may be filled with the polysilicon 513 doped with impurities (e.g., n-type impurities). Then, as shown in FIG. 16, the upper portion of the doped polysilicon (e.g., polysilicon 513 of FIG. 15) may be removed through grinding, CMP, and/or etching processes to form the first pad 510. Thereafter, a source structure (e.g., the source structure 200 of FIG. 5A) may be formed on the upper portion of the first pad 510.

Referring to FIG. 16, the core insulator 440 may include the main portion 441 and the extended portion 442. The main portion 441 may be a column portion having a longitudinal direction (e.g., vertical direction D3). The extended portion 442 may be a portion with a greater width than the main portion 441 at the top of the main portion 441.

Through FIGS. 6 to 16, a process of forming the channel structure 400 and the first pad 510 has been described, but this is merely an example and the process of forming the channel structure 400 and the first pad 510 is not limited thereto. For example, in the above-described process, some processes may be omitted or changed, certain other processes may be added, or the order may be changed.

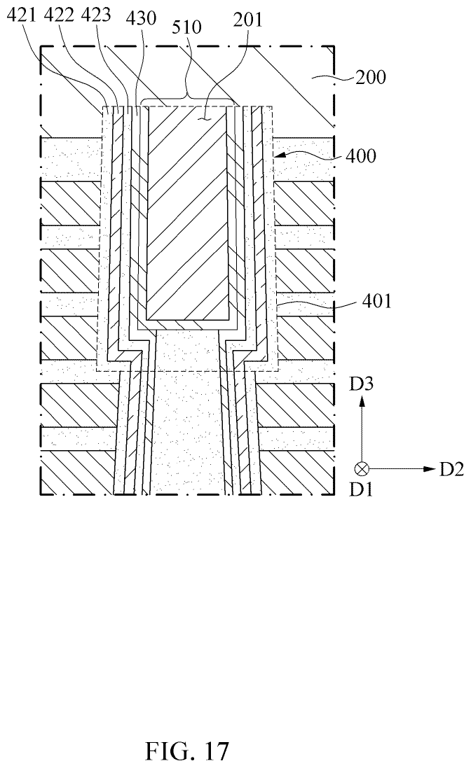

FIG. 17 is a schematic cross-sectional view illustrating an example of an upper end portion of a channel structure.

Referring to FIG. 17, the source structure 200 includes a recess 201 into which the upper end of the channel structure 400 is inserted and positioned. For example, the blocking layer 421, the information storage layer 422, the tunneling layer 423, the channel poly layer 430, and the first pad 510 of the first pad portion 401 may be inserted into the recess 201 of the source structure 200. For example, in the state shown in FIG. 12, the source structure 200 may be formed after an insulating layer outside the channel structure 400 positioned on the upper portion is partially etched, thereby forming the recess 201.

As described above, although the embodiments have been described with reference to the limited drawings, a person skilled in the art may apply various technical modifications and variations based thereon. For example, suitable results may be achieved if the described techniques are performed in a different order, and/or if components in a described system, architecture, device, or circuit are combined in a different manner, or replaced or supplemented by other components or their equivalents.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Therefore, other implementations, other embodiments, and equivalents of the claims are within the scope of the following claims.

What is claimed is:

1. A semiconductor device comprising:
a stacked structure comprising a plurality of gate electrodes and a plurality of interlayer insulating layers, the plurality of gate electrodes and the plurality of interlayer insulating layers being alternately stacked;
a source structure positioned on an upper portion of the stacked structure;
a bit line positioned on a lower portion of the stacked structure; and
a channel structure penetrating the stacked structure and connected to the source structure and the bit line,
wherein the plurality of gate electrodes comprise:
a first erase control gate electrode positioned on an upper end portion of the stacked structure; and
a plurality of word lines on a lower side of the first erase control gate electrode, wherein the channel structure comprises:
a first pad portion, wherein the first pad portion is an upper end area of the channel structure, and the first pad portion protrudes from the source structure to a position that overlaps the first erase control gate electrode in a horizontal direction; and
a channel portion, wherein the channel portion is positioned on a lower side of the first pad portion and comprises a core insulator that at least partially penetrates the plurality of word lines,
wherein a largest width of the first pad portion is larger than a smallest width of the channel portion.

2. The semiconductor device of claim 1, wherein the first pad portion has a largest width at a position where the first pad portion is connected to the channel portion, and
wherein the channel portion has a smallest width at a position where the channel portion is connected to the first pad portion.

3. The semiconductor device of claim 2, wherein the channel structure has a width that is discontinuously narrowed at a position where the first pad portion and the channel portion are connected.

4. The semiconductor device of claim 1, wherein the channel structure further comprises a gate dielectric layer and a channel poly layer stacked sequentially from outside to inside along a horizontal direction.

5. The semiconductor device of claim 4, wherein at least a portion of the gate dielectric layer or the channel poly layer is bent inward to have a narrow width at a position where the first pad portion and the channel portion are connected.

6. The semiconductor device of claim 4, wherein the first pad comprises:
a first layer positioned inside the channel poly layer and comprising undoped polysilicon; and
a first pad core positioned inside the first layer and comprising doped polysilicon.

7. The semiconductor device of claim 6, wherein the first layer comprises:
a first side wall layer surrounding an outer peripheral surface of the first pad core; and
a first lower layer covering a lower surface of the first pad core.

8. The semiconductor device of claim 1, wherein the number of first erase control gate electrodes is more than one, and
wherein the first pad overlaps at least a portion of the plurality of first erase control gate electrodes in a horizontal direction.

9. The semiconductor device of claim 8, wherein a lower end portion of the first pad overlaps a lowermost first erase control gate electrode positioned on a lowermost side of the plurality of first erase control gate electrodes in a horizontal direction, or
wherein the lower end portion of the first pad is positioned above the lowermost first erase control gate electrode.

10. The semiconductor device of claim 1, wherein the first pad portion is an area filled with a metal material to limit an etching depth during a process of forming the channel structure in the stacked structure.

11. The semiconductor device of claim 4, wherein the plurality of gate electrodes further comprise a second erase control gate electrode positioned on a lower end portion of the stacked structure, and
wherein the channel structure further comprise a second pad portion, the second pad portion is a lower end area of the channel structure, the lower end area is positioned on a lower side of the channel portion, and a second pad overlaps the second erase control gate electrode in a horizontal direction.

12. The semiconductor device of claim 11, wherein the second pad comprises:
a second layer positioned inside the channel poly layer and comprising undoped polysilicon; and
a second pad core positioned inside the second layer and comprising doped polysilicon.

13. The semiconductor device of claim 1, wherein an upper end portion of the core insulator is positioned on the first pad portion.

14. The semiconductor device of claim 13, wherein the core insulator comprises a main portion and an extended portion having a wider width than the main portion on an upper end of the main portion.

15. The semiconductor device of claim 1, wherein the source structure comprises a recess in which the upper end of the channel structure is positioned.

16. An electronic system comprising:
a main substrate;
a semiconductor device disposed on the main substrate; and
a controller disposed on the main substrate and electrically connected to the semiconductor device,
wherein the semiconductor device comprises:
a stacked structure comprising a plurality of gate electrodes and a plurality of interlayer insulating layers, wherein the plurality of gate electrodes and the plurality of interlayer insulating layers are alternately stacked;
a source structure positioned on an upper portion of the stacked structure;
a bit line positioned on a lower portion of the stacked structure; and
a channel structure penetrating the stacked structure to connect the source structure and the bit line,
wherein the plurality of gate electrodes comprise:
a first erase control gate electrode positioned on an upper end portion of the stacked structure; and
a plurality of word lines on a lower side of the first erase control gate electrode,
wherein the channel structure comprises:
a first pad portion, wherein the first pad portion is an upper end area of the channel structure, wherein the first pad protrudes from the source structure to a position that overlaps the first erase control gate electrode in a horizontal direction; and
a channel portion positioned on a lower side of the first pad portion and comprising a core insulator, wherein at least a portion of the core insulator penetrates the plurality of word lines is positioned, and
wherein a largest width of the first pad portion is larger than a smallest width of the channel portion.

17. The electronic system of claim 16, wherein the first pad portion has a largest width at a position where the first pad portion is connected to the channel portion, and
wherein the channel portion has a smallest width at a position where the channel portion is connected to the first pad portion.

18. The electronic system of claim 16, wherein the channel structure further comprises a gate dielectric layer and a channel poly layer stacked sequentially from outside to inside along a horizontal direction.

19. The electronic system of claim 18, wherein at least a portion of the gate dielectric layer or the channel poly layer is bent inward to have a narrow width at a position where the first pad portion and the channel portion are connected.

20. The electronic system of claim 18, wherein the first pad comprises:
a first layer positioned inside the channel poly layer and comprising undoped polysilicon; and
a first pad core positioned inside the first layer and comprising doped polysilicon.
